(19) United States
(12) Patent Application Publication
(10) Pub. No.: US 2016/0230025 A1
(43) Pub. Date: Aug. 11, 2016

(54) COMPOUND TO FORM ELECTRICAL TRACKS INTO

(71) Applicant: TRYONIC LTD, London Greater London (GB)

(72) Inventor: Fabio CAPPELLI, London (GB)

(73) Assignee: TRYONIC LTD, London Greater London (GB)

(21) Appl. No.: 14/908,454

(22) PCT Filed: Aug. 3, 2014
(86) PCT No.: PCT/IB2014/063658

§ 371 Date: Jan. 28, 2016

(30) Foreign Application Priority Data
Aug. 3, 2013 (IT) TV2013A000128

(51) Int. Cl. C09D 5/24; C09D 101/02; B23K 26/00; B23K 26/36; H05K 3/10; H05K 1/09

(52) U.S. Cl. CPC C09D 5/24; H05K 3/105; H05K 1/092; B23K 26/0006; B23K 26/36; C09D 101/02; H05K 2203/107

(57) ABSTRACT

A method is described for making electrically conductive tracks or areas within a material. By using as material cellulose or its derivatives; and by locally raising the temperature of a portion of the material, one can trace tracks in a simple, economic and fast way manner.

The invention concerns a compound, e.g. to be spread or sprayed on any surface, in which to realize conductive circuits or tracks to carry electrical charges, or voltage or current signals. The compound is modifiable to locally vary its electrical conductivity.

To wire surfaces or equipments is known to be a very expensive and laborious operation. The length of the cables, their cost and weight often account for a predominant part, sometimes up to advise against the beginning of the work.

WO/2012/137048, for example, teaches how to create conductive paths inside the volume of a compound, thanks to polarizable molecules via laser. The compound here, however, has a complex formula, and the use of a laser can disadvantageously limit the areas of application.

This raises the problem of obtaining a compound of the aforementioned type which has a simple formula, and therefore inexpensive and easily reproducible.

In addition, it is convenient to break free from the use of a laser for tracing the tracks.

At least one problem is solved by the compound and/or method and/or use as in the attached claims, in which the dependent ones define advantageous variants.

Percentages described below are percentages by weight with respect of the total, unless otherwise specified.

Cellulose (C₆H₁₀O₅) and the class of substances derived from it proved to be a surprisingly good material in which to obtain electrically conductive tracks. In particular, advantageous is the difference (decrease) of electrical resistivity which is obtained by burning or heating a portion of cellulose making it carbonize.

Note that the cellulose in the prior art is used at most as insulation around metallic conductors.

In particular, it was unexpectedly found that the nitrocellulose, a cellulose subspecies, provides the results of lower resistivity than the cellulose, therefore electrical paths of better quality. And it is also more easily sprayable and diluted, so it can be vaporized better and more easily.

Nitrocellulose (or cellulose) generally has a resistivity of an insulator at room temperature. Taking it approximately to 220-230° C. it carbonizes, and its resistivity drops in the range of semiconductors. The change in electrical resistance for more electrically conductive tracks or areas is exploited to create e.g. conductive pathways ad hoc, ex novo or in real time, or to manage logical states represented by voltages or currents.

Preferably to locally raise the temperature of the cellulose or nitrocellulose in order to carbonize it and trace the track, a laser is used, which gives comfort and precision tracing. But one can also use other methods of heating/tracing, e.g. by putting in the oven or burning with a heat source sections of (nitro)cellulose, e.g. the hot rod of a tin-plater. Burning, however, operates in a poorly controlled way, the results are not repeatable with high precision, but for medium accuracy is sufficient.

For example, in the laboratory on an insulating base was spread a layer of nitrocellulose, and on it (see below how) a 7 cm long, 0.9 mm wide and about 7 mμ deep track, was derived. The layer of nitrocellulose was 50 μm thick and above it a laser beam was run. From a virtually infinite resistivity the nitrocellulose track has come to a resistance of 3500Ω.

Advantageously with the same results each type of nitrocellulose can be used, e.g. mononitric (C₂H₃₉O(NO₂)₁₂O₂₀), binitric, trinitric, etc, up to dodecanitric (C₂H₂₈(NO₂)₁₂O₂₀.

To improve the electrical performance, to the material particles of noble materials are added (e.g. silver, copper, gold, platinum, indium, tungsten). Gold has high costs, and except for silver all the others work with lower performance. The addition of these particles has yielded surprising results. Even though they are a conductive material themselves, the mere introduction of the particles in the material would not lead to an increase of the total electrical conductivity, due to a layer of insulating oxide that inevitably forms around each particle. However, the conductivity actually improves, provided that the particle size and/or their density have certain values. The best results were obtained with particles, in particular silver particles, with an average diameter of 5 μm to 17 μm, with a conductivity peak detected for diameters of 9 μm to 11 μm. The average or optimal particle size or diameter is preferably 11 μm, for example with a composition of the particles equal to: 34% with a diameter of 12-18 μm; 50% with a diameter of 11 μm; 16% with a diameter of 3-5 μm.

In particular for silver powder or silver particles, the percentage by weight of 3% to 20%, even more in particular 5% to 12%, have allowed to obtain good electronic performance.

The effect is explained theoretically considering that by the local increase of temperature the oxide layer explodes and its fragments remain near the core of the particle. On the various exposed nuclei an electron cloud would form being large enough to communicate electronically with the near one, from this the improved conductivity.

Preferably the compound or material is applied to a surface by a brush, spraying or cold drawing. In order to favor the application, to the mixture a solvent is added, which acts as a diluent and then evaporates after spraying. One can use e.g. dichloromethane, or organic solvents (e.g. tetrachlorethylene, acetone, methyl acetate, ethyl acetate, hexane).

Preferably to the compound a glycol is added, e.g. PEG (polyethylene glycol). A percentage that has given good results is 1-4%.

The effect is to keep soft or flexible the compound when the solvent is evaporated, in order to avoid cracks or lesions when the support is deformed or there are e.g. temperature excursions. It is also possible to mechanically deform the layer of compound when or almost solidified, allowing e.g. the movement of movable elements inside it.

Preferably, to the compound a (food or acrylic) dye is added; with a percentage that has given good results of about 2%. So the laser absorption for the compound is improved. The laser could go through the compound without heating or burning it, and/or without acting on the particles made of noble material (v. below).

It is also proposed a method for making electrically conductive tracks or areas within a material. The method shares the advantages already described for the compound, and vice versa. The method is characterized by the steps of

using as material cellulose or its derivatives;

locally raising the temperature of a portion of the material.

As optional steps of the method, either alone or in combination:
a laser is used to locally raise the temperature of a portion of the material;
nitrocellulose is used for material;
in the material silver or copper or gold or platinum or indium or tungsten particles are inserted, having an average diameter of 5 μm to 17 μm, and percentage by weight with respect to the material that contains them of 3% to 20%;
said average diameter is 10-11 μm;
a glycol is added, e.g. PEG (polyethylene glycol), to the material;
a solvent is added, e.g. diethyl ether, to the material;
a food or acrylic dye is added to the material.

Another aspect of the invention is the use of cellulose or its derivatives as a material in which to create electrically conductive areas or tracks by raising the local temperature of a portion of the material.

The above-defined use has many particularizations, e.g. that the material is nitrocellulose. Every feature of the method or compound as claimed or described in this application may be characteristics of use claims.

Note that the aforementioned rise in temperature in the material can only serve to carbonize it and increase its electrical conductivity. A first effect is therefore an increase of conductivity of the material. Further drops of resistivity are achieved through the interaction of the laser with particles dispersed in the cellulose, see below. The localized supply of heat and energy, therefore, can act also on the dispersions within the matrix of cellulose, and the resistivity is even lower just because of the fact that such dispersions are within the cellulose. The said compound also allows a tracing of the track in an automatic way: when a voltage is applied between two points of the compound a track will form between them.

The advantages of the invention will be clearer from the following description of a preferred embodiment of the compound, making reference to the attached drawing in which

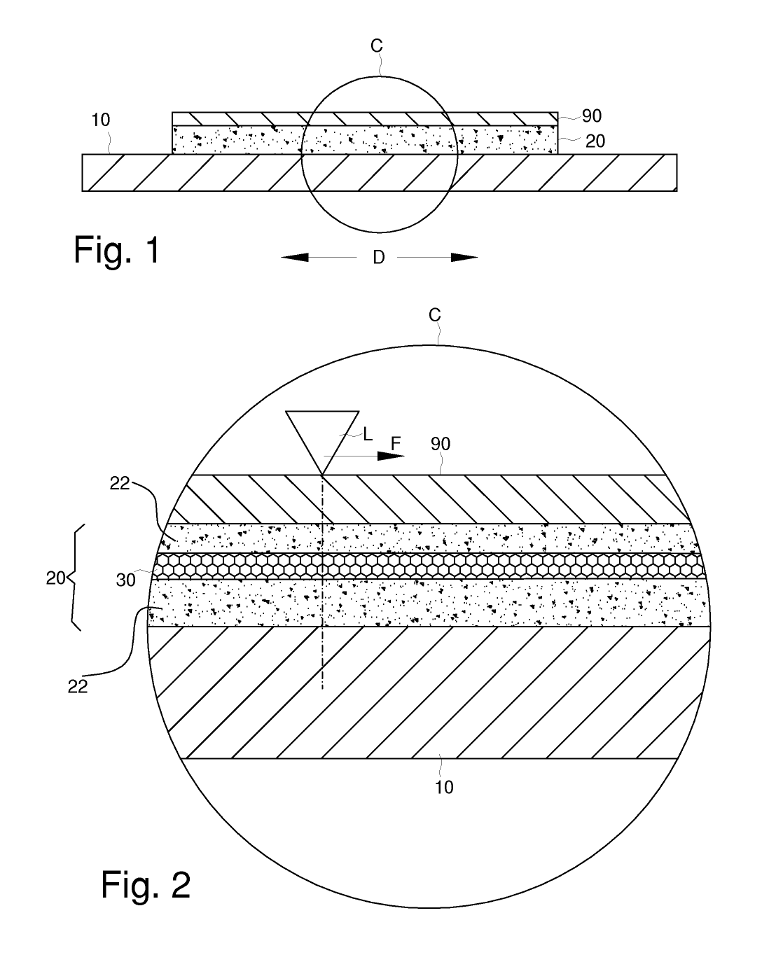

FIG. 1 shows a layer composed as laid down;

FIG. 2 shows a magnification of the compound of FIG. 1;

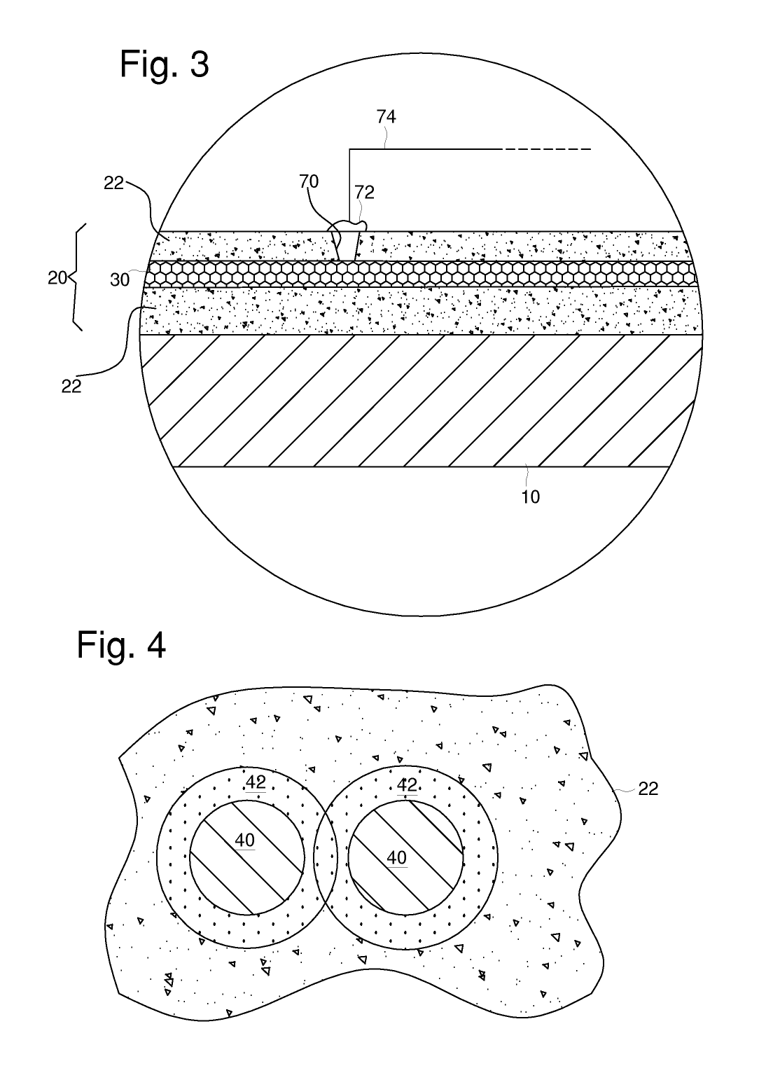

FIG. 3 shows the compound of FIG. 3 in particular configuration;

FIG. 4 shows particles present in the layer of FIG. 1.

On a generic support surface 10, e.g. a wall, a metallic body, a printed circuit board (PCB) or a layer of glass, polyacetate or acrylic, there is spread or sprayed a layer 20 of compound.

The compound 20 can be formed like this (by volume):
16% of micrometric silver powder (with a particle size as specified above)
40% collodion (6% solution of nitrocellulose in ethanol or a ethanol/diethylether mixture);
40% diluent, where the diluent is composed of: 76% butyl acetate, 12% ethanol, 8% toluene, 4% ethylcellulose;
2-4% PEG;
2% (optional) of additive sensitizer to optimize the irradiation by laser light, e.g. pigment red 112, iupac name: 2-Naphthalenecarboxamide, 3-hydroxy-N-(2-methylphenyl)-4-[(2,4,5-trichlorophenyl)azo].

Another formulation of the compound 20, the most simple, can be:
97% to 80% nitrocellulose;
silver powder or silver particles: 3% to 20%, or better 5% to 12%, to obtain good electronic performance.

The nitrocellulose in the previous example (by its unit of weight) is regarded as commercially purchased, and can contain other components that constitute the said solvent, e.g. 98% to 90% diethyl ether+methanol, or 35% to 70% diethyl ether+65% to 30% methanol, and 2% to 10% semi-synthetic cellulose. For example, exact values in the nitrocellulose are: nitrocellulose 6% and ethyl ether+methanol 94%. The percentage of solvent is not critical, however.

The values quoted for the doses of the various components of the compound are those resulted optimal experimentally, but individual percentage changes are possible, e.g. by ±15%.

In general then a generic formula can be:

nitrocellulose: 2% to 10%;

silver powder or silver particles (as described before): 3% to 20%, or better 5% to 12% to obtain good electronic performance,

remaining %: solvent as described before.

The production of the compound does not require special care, it is enough to put the components together and mix them. For example, the components may be mixed directly in the tank of an airbrush, e.g. by the agitation of a magnet. Or the nitrocellulose is mixed with the PEG, the solvent is added, blending, and finally one adds the dye (optional).

Once laid, the compound 20 dries and hardens in 3-5 minutes; or one can bake it at about 80° C. for 5-6 seconds.

For the silver particles or powder (or other noble material), one can use what is commercially available (e.g. by firm Heraeus Precious Metals GmbH & Co. KG).

The particle diameter can range from some μm to a few dozen mμ, and the best experimental results were obtained with a diameter, also average diameter, of about 10-11 μm. An experimented case with average diameter of 10 μm had the following particle size for the particles: 34% at 12-18 μm; 50% at 11 μm; 16% at 3-5 μm=average value 11 μm or 7 μm, with all values comprised within this range.

After spraying of the compound 20, the silver particles are distributed forming a layer 30 fairly uniform inside the layer of cellulose 22 (FIG. 2). The weight of silver is not sufficient to get it to fall completely towards the support 10, so it floats on the nitrocellulose thanks to the greater molecular size of the latter. If the particles have a diameter less than 5 or 6 μm the tracks in the compound begin to lose the conductivity characteristics, or one is unable to create them. Not only are the particles “floating” on the (nitro)cellulose (which prevents tracks inside its volume), but even doing a superficial, mono-track sample the electrical conduction is poor because the electronic clouds are small. If the particles are too large, however, they sink before the (nitro)cellulose creates a lattice and the layer 30 does not come out. In other words the ranges of value for the particle size within which the compound works must be—surprisingly—respected with good precision. Greater or lesser values have been tried experimentally but satisfactory results have not been obtained. The reason is that there is precipitation on the bottom of the compound when the particles are too large or they do not fall inside the compound when they are too small.

On a layer of compound 20 with a thickness of 50 μm the layer 30 of silver arranges at about 35 μm from the support 10, and is about 7 μm thick.

Then a laser L is run over. The laser beam is sent in the compound 20, in the direction substantially perpendicular to the largest dimension D of the support 10, and it moves along the layer 20 to create a track (direction F).

The laser L has focal length such as to reach and act on the layer of particles. It breaks down and blows off the oxide layer that surrounds the particles. Then, around a particle of silver 40 (FIG. 4) an electron cloud 42 will form that on average manages to touch that of a neighboring particle. Even if the particles 40 are separated by a micrometric segment of carbonized nitrocellulose (on average 2-3 μm), and thus still more conductive than before the laser L passed, the segment is shunted in parallel by the cloud 42, and the overall conductivity of the layer 30 becomes unexpectedly much higher.

Putting a lot of particles degrades performance, because the layer 30 becomes a nearly uniform and indistinct diffusion in the volume of (nitro)cellulose.

In the laboratory, samples were prepared for experimenting the tracing by depositing the compound 20 on different plastic substrates. The compound 20 was applied by spraying, in five successive coats.

Usually 80% of the solvent leaves by evaporation, and there remain 50 μm of compound (nitrocellulose+silver+10% solvent).

The final thickness of the layer of deposited compound 20 was about 200 μm. A 4 cm long, 1 mm wide and thickness of average 7 microns track was traced, with the greater particle size of silver.

Polyethylene film:

Resistance of the track: 2 ohms (Dielectric greater than 1 GΩ).

Silicone rubber (reinforced with carbon fibers):

Conductivity of the track after the passage of the laser L: 2Ω (Dielectric greater than 1 GΩ).

Excellent adhesion of the compound on the support.

Epoxy resin (Epichlorohydrin+BFA) reinforced with carbon fibers:

Conductivity of the track after the passage of the laser L: 2Ω (Dielectric greater than 1 GΩ).

Polystyrene:

Conductivity of the track after the passage of the laser L: 2Ω (Dielectric greater than 1 GΩ).

The best conductivity was experimented with particles 40 having diameter, also average diameter, of 10 μm, and/or with an empty/full ratio between nitrocellulose and particles 40 of about 0.5.

As laser L a laser was used at 480 μm with a 27-28 mm focal. It is preferred that the specific power of the laser is 0.6 W/mm*s, and that the laser moves with the speed of 1 mm/sec (direction F).

For protection, one can overlap the traced compound 20 with a protective layer 90, for example acrylic or polyvinyl-alcohol (which also absorbs any residual water captured by the compound 20 during spraying).

To create multiple layers of overlapping tracks one can spray a layer 20, create a track in it, overspray another layer 20, create a track in it, and so on. Between a layer 20 and the next one, the protective layer 90 can be inserted.

To access the traced track one can pierce the layer 20 (FIG. 3), e.g. by a laser, to open a channel 70 in the nitrocellulose until reaching the track in the layer 30 of particles. Into the channel 70, for example with a syringe or dispensing element, silver or liquid conductive material is poured and a conductive connection 74 is immersed therein. The liquid conductive material solidifies and permanently connects the inner track to the outside.

1. A method for making electrically conductive tracks or areas within a material, said method comprising the steps of:
using as the material, cellulose or its derivatives; and
locally raising the temperature of a portion of the material.

2. The method according to claim 1, wherein a laser locally raises the temperature of a portion of the material.

3. The method according to claim 1, wherein the material is nitrocellulose.

4. The method according to claim 1, wherein silver or copper or gold or platinum or indium or tungsten particles are inserted in the material, having an average diameter from 5 μm to 17 μm, and percentage by weight with respect to the material that contains them from 3% to 20%.

5. The method according to claim 1, wherein a glycol is added to the material, and/or a solvent is added to the material.

6. A compound inside which to form electrically conductive tracks or areas, the compound comprising by weight:
cellulose or a derivative thereof from 2% to 10%;
particles of silver or copper or gold or platinum or indium or tungsten, having an average diameter from 5 μm to 17 μm, and percentage by weight from 3% to 20%; and
solvent, the remaining %.

7. The compound according to claim 6, wherein the derivative is nitrocellulose.

8. The compound according to claim 6, wherein the average diameter is 10-11 μm.

9. The compound according to claim 6, comprising a glycol.

10. A method of using cellulose or a derivative thereof as a material in which to form electrically conductive tracks or areas through local increase of temperature of a portion of the material.

11. The method according to claim 1, wherein PEG (polyethylene glycol) is added to the material, and/or ethyl ether is added to the material.

12. The compound according to claim 6, comprising a PEG (polyethylene glycol) of 2-4%.
